(19) United States
(12) Patent Application Publication
(10) Pub. No.: US 2011/0221456 A1
(43) Pub. Date: Sep. 15, 2011

(54) SENSOR SYSTEM AND METHODS FOR ENVIRONMENTAL SENSING

(75) Inventors: Jody Alan Fronheiser, Selkirk, NY (US); Don Mark Lipkin, Niskayuna, NY (US); Peter Micah Sandvik, Niskayuna, NY (US); Todd Michael Striker, Ballston Lake, NY (US); Martin Mathew Morra, Glenville, NY (US)

(73) Assignee: GENERAL ELECTRIC COMPANY, SCHENECTADY, NY (US)

(21) Appl. No.: 12/721,916

(22) Filed: Mar. 11, 2010

(51) Int. Cl. G01N 27/22; G01R 27/26; C04B 35/565; G01N 1/00; C04B 35/58; G01R 27/08

(52) U.S. Cl. 324/663; 324/658; 501/92; 422/119; 324/691

(57) ABSTRACT

A sensor system, and an associated method for detecting harsh environmental conditions, is provided. The sensor system includes at least one sensor having an electrical sensing element. The electrical sensing element is based on certain classes of composite materials: (a) silicon carbide (SiC); (Mo,W)₅Si₃C; (Mo,W)Si₂; or (b) (Mo,W)₅Si₃C; (Mo,W)Si₂; (Mo,W)₅Si₃. The sensor system is useful for determining harsh environmental conditions. Gasification systems, which include at least one of the sensor systems are also described.

### FIELD

The invention relates to sensors and methods for detection of environmental conditions, and more particularly to sensors and methods for physical and physical-chemical sensing applications.

### BACKGROUND

Key performance indicators for sensors used in harsh environments include the ability to withstand extreme environmental conditions, and high selectivity and sensitivity. Therefore, an appropriate selection of sensor materials is one of the considerations in sensor performance and application.

A non-limiting example of a material which has been used for harsh environment resistant applications is a refractory composite material. A typical refractory material such as silicon carbide is a known heat-resistant material produced by powder metallurgy techniques. In some cases, the disadvantage of the material is high porosity and the tendency for crack formation, especially after temperature cycling. The material can have insufficient stability during temperature cycling (repeated heating to working temperatures and cooling down after the operation), and under abrupt temperature change conditions.

The materials conventionally used to shield thermocouples and to form fiber optic sensors in high temperature environments often include a dense silicon carbide (SiC) ceramic material, such as Hexylloy™. These materials are capable of withstanding some high-temperature environments, but may not withstand the thermo-mechanical or thermo-chemical environment present in high-temperature equipment and systems, e.g., combustion systems or gasifier systems.

Therefore, there is a need for a sensor that is capable of withstanding harsh environments e.g., high temperature, high pressure, and harsh thermomechanical or thermochemical conditions. The sensor should also exhibit sufficient sensitivity to changes in environmental conditions.

### BRIEF DESCRIPTION

One or more of the embodiments of the invention provides a sensor system and method for detecting environmental conditions by using the sensor. The sensor system comprises a sensing element which is especially resistant to harsh environmental conditions.

In one embodiment, a sensor system is provided. The sensor system comprises at least one sensor, which comprises an electrical sensing element. The electrical sensing element comprises a composite material selected from the group consisting of (a) and (b); wherein (a) comprises silicon carbide (SiC), (Mo,W)₅Si₃C, and (Mo,W)Si₂; and (b) comprises (Mo,W)₅Si₃C, (Mo,W)Si₂, and (Mo,W)₅Si₃.

The sensor can be responsive to at least one environmental condition or environmental event. The sensor comprises a resistive sensing element, wherein the resistive sensing element is formed of a composite material as mentioned above, and further described below. The sensor system further comprises a power supply capable of delivering electrical power to the resistive sensing element; and a voltage-measuring device to measure a voltage difference across the resistive sensing element.

In yet another embodiment, the sensor comprises a capacitive sensing element, wherein the capacitive sensing element comprises two electrodes; and is formed of a composite material as described herein. The sensor system further comprises a power supply capable of delivering electrical power to the capacitive sensing element; and a capacitance measuring device to measure a capacitance across the capacitive sensing element.

In another embodiment, a gasification system is provided, wherein the gasification system comprises a gasifier, and at least one sensor system disposed on or within at least one wall of the gasifier. The sensor system comprises at least one sensor, which comprises an electrical sensing element. The electrical sensing element comprises a composite material selected from the group consisting of (a) and (b); wherein (a) comprises silicon carbide (SiC), (Mo,W)₅Si₃C, and (Mo,W)Si₂; and (b) comprises (Mo,W)₅Si₃C, (Mo,W)Si₂, and (Mo,W)₅Si₃. The sensor system further comprises a power supply delivering electrical power to the electrical sensing element, and an electrical measuring device to measure an electrical property across the electrical sensing element.

### DRAWINGS

These and other features, aspects, and advantages of the present invention will become better understood when the following detailed description is read with reference to the accompanying drawings in which like characters represent like parts throughout the drawings, wherein:

FIG. 1 is a top view of an embodiment of a sensor circuit comprising a resistive sensor element.

FIGS. 2A and 2B illustrate sensing configurations of a sensor system, before and after a change in a dimension of an associated substrate, respectively, wherein the sensor system comprises a resistive sensor.

FIGS. 3A and 3B illustrate sensing configurations of a sensor system, before and after a change in a dimension of an associated substrate, respectively, wherein the sensor system comprises three resistive sensors.

FIG. 4 is a top view of an embodiment of a sensor circuit comprising a capacitive sensor element.

FIGS. 5A and 5B illustrate sensing configurations of a sensor system, before and after a change in a dimension of an associated substrate, respectively, wherein the sensor system comprises a capacitive sensor.

FIGS. 6A and 6B illustrate sensing configurations of a sensor system, before and after a change in a dimension of an associated substrate, wherein the sensor system comprises three capacitive sensors.

FIGS. 7A and 7B are photographs showing a cast iron part which is exposed to a high temperature copper (Cu) melt.

FIG. 8 is a photograph showing a Hexylloy™ (commercial silicon carbide) test-piece, which does not include a refractory silicide coating material.

FIGS. 9A and 9B are photographs showing a deposition of Cu melt material on the surface of a block made of refractory silicide material, and of a cast iron test-piece coated with refractory silicide material, respectively.

FIG. 10 shows a brick wall in a gasification chamber with a distribution of harsh environment sensors that monitor the physical degradation of the brick.

FIG. 11 shows a graph illustrating resistance as a function of temperature of a refractory composite material.

These and other features, aspects, and advantages of the present invention will become better understood when the following detailed description is read with reference to the accompanying drawings.

### DETAILED DESCRIPTION

Embodiments of the present invention include a sensor system comprising an electrical sensing element, wherein the electrical sensing element is a composite material, and associated methods for detecting environmental conditions.

In the following specification and claims, the singular forms “a”, “an” and “the” include plural referents unless the context clearly dictates otherwise.

As used herein, the term “sensor element” or “sensing element” refers to any component which is responsive to a physical or a chemical stimulus, and which transmits a measurable impulse or signal as a result of that stimulus. Thus, the sensor element may be in the form of a conductor, e.g., an electrical conductor. These conductors may conduct electricity between any feature in the device and any attached component, e.g., a power source, an electrical detection component, a signal processor, and the like. (These attached features may be directly attached to the sensing element, or they may be indirectly attached.)

The invention provides a sensor system comprising a sensor material that is resistant to harsh environment conditions. As used herein, the term “harsh environment condition” refers to an environment having one or more of the following conditions: high-temperature (T>250° C.), high-pressure (P>0.7 MPa), high-voltage (>1000V), high current (>1000 A), highly-corrosive aqueous solution (pH>10 or pH<4), high gamma-radiation (y-ray dosage>1000 Mgy), or a hot neutron flux (>1018 n/cm2s). A harsh environment may further include conditions such as high-humidity (RH>85%), high-vibration (f>1 Hz), corrosive gases (e.g., H₂S, HCl, CO, SO₂), or combinations thereof. Non-limiting examples of a harsh environment further include a chemical or thermo-chemical reactive environment, and exposure to mechanical stresses, such as vibration, strain, erosion or physical damage from debris within the system. Chemically reactive environments include oxidizing, reducing or corrosive environments. Examples of oxidizing environments include, but are not limited to, water and oxygen. Reducing environments include but are not limited to hydrogen and hydrocarbons; and corrosive environments include but are not limited to sulfidizing and halide environments.

A specific example of a harsh environment is the interior environment of a gasification system, where corrosion may result from hydrogen sulfide, chloride, or oxide slag (e.g., CaO—Al₂O₃—SiO₂—FeO—MgO) present in the system. In one embodiment, mechanical stresses develop from material strain due to thermal cycling or thermal mismatches. Erosion occurs as slag moves down in the gasification chamber, and as slag, ash, or large pieces of debris accumulate to form a coating, or to degrade elements. Additionally, in the gasifier environment, thermo-chemical reactions can result in changes in a substrate (e.g., a refractory brick liner) and/or changes in the refractory silicon carbide sensing material chemistry, while subjected to elevated temperatures. Thermally induced phase changes in the sensor element can also alter resistance.

As used herein the term “change in resistance” or “change in capacitance” refers to a change occurring in the sensing element due to one or more environmental changes. Environmental changes include, but are not limited to, erosion of the refractory brick liner in which the sensor is disposed. A change in a dimension, by wear, erosion, solid state diffusion, or corrosion of the liner, leads to a change in sensor resistance or sensor capacitance, which can be measured.

As used herein the term “substrate” refers to the electrically insulating material on which the refractory silicon carbide sensing material is disposed. In addition to providing electrical insulation, the substrate may provide mechanical support and may further protect the sensor from the harsh environment. In some cases, the term substrate is also used to refer to the substance within or on top of which the sensors are disposed. This may include, for examples, refractory bricks, which are used to form the liner of a gasifier system, low alloy steels which are often used to form the pressure vessel wall of a gasifier system, and non ferrous metals which are often used to construct the heat exchanger of a gasifier system

As used herein the term “degradation of a substrate” refers to a change in the substrate, caused by erosion, thermo-chemical etching, or catastrophic events in the sensing environment. The environmental events result in the degradation or change in the physical size or shape of the substrate material, which may decrease or increase, and/or may cause the formation of cracks in the substrate. “Resistant to degradation” means resistant to the changes mentioned above.

As used herein the term “optimal operational resistance” refers to a range of resistance values, which are optimum for processing the electrical signal from the sensor system under normally operating conditions. Typically the value of optimal operational resistance ranges between greater than 0.010 ohms and less than 10,000 ohms.

Various embodiments of the present invention describe a sensor system, which includes at least one sensor comprising an electrical sensing element, wherein the electrical sensing element comprises a composite material. The sensor system may further comprise a power supply, which is capable of delivering electrical power to the electrical sensing element; and a measuring device to measure at least one change in an electrical property, across or within the electrical sensing element. In one embodiment, the sensor may be operative in a harsh environment.

The sensing characteristics of the composite material can be modified and enhanced by changing the amount and type of silicide constituent present in the material, based in part on the particular type of “harsh environment”. The addition of silicides having various compositions, stoichiometries and phase fractions results in a material with different microstructural characteristics (mutual disposition of the phases, their size and shape, crystallographic orientation, etc.) and, hence, with different combinations of the indicated useful properties. A higher concentration of the silicide-alloying elements may decrease the electrical resistivity. Some compositions of the sensor material are expected to provide excellent thermal shock resistance. Other compositions may also withstand multiple water quenches from 1500° C., without visible degradation. This sensor composition may also provide good sulfidation resistance. The material is often resistant to erosion by gasifier slag, and can have higher thermal and electrical conductivity than prior art sensor materials.

The composite material of the sensor comprises either a combination of silicon carbide (SiC), (Mo,W)₅Si₃C, and (Mo,W)Si₂; or (Mo,W)₅Si₃C, (Mo,W)Si₂, and (Mo,W)₅Si₃. In the composite sensor material, the molar ratio of tungsten to molybdenum may be in the range from about 0:1 to about 9:1.

In regard to adjustments in sensor material constituents, an increase in the relative content of tungsten, at the expense of molybdenum, usually increases the heat resistance and the resistance to thermal shock and temperature cycling characteristics.

In some specific embodiments, the composite material has the following ratio of components (vol. %):

| (Mo,W)₅Si_{3;} or (Mo,W)₅Si₃C | About 15% to about |
|---|---|
| | 85% |
| Silicon carbide | about 2% to about |
| | 85% |
| (Mo,W)Si₂ | about 0.8% to about |
| | 55%; |

In one embodiment, the elemental substitutions for (W, Mo) may be selected from Nb, Ta, or Re (may be up to about 30%). In another embodiment, (W, Mo) may be substituted by Hf, Zr, or Ti (may be up to about 5%). In an alternative embodiment, Si may be substituted by Ge, up to about 100%. In one embodiment, carbon can be substituted by boron up to about 20%.

In some embodiments of this invention, the composite material comprises pores occupying up to about 40% of the volume of the material. The porosity is useful for increasing the electrical resistance, or increasing the thermal shock resistance of the material.

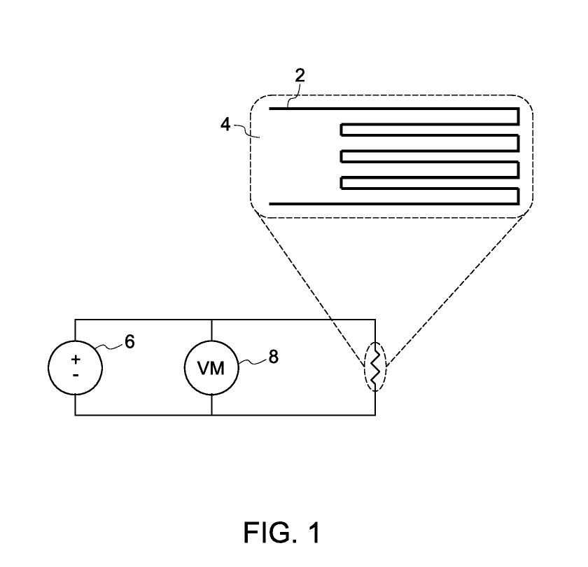

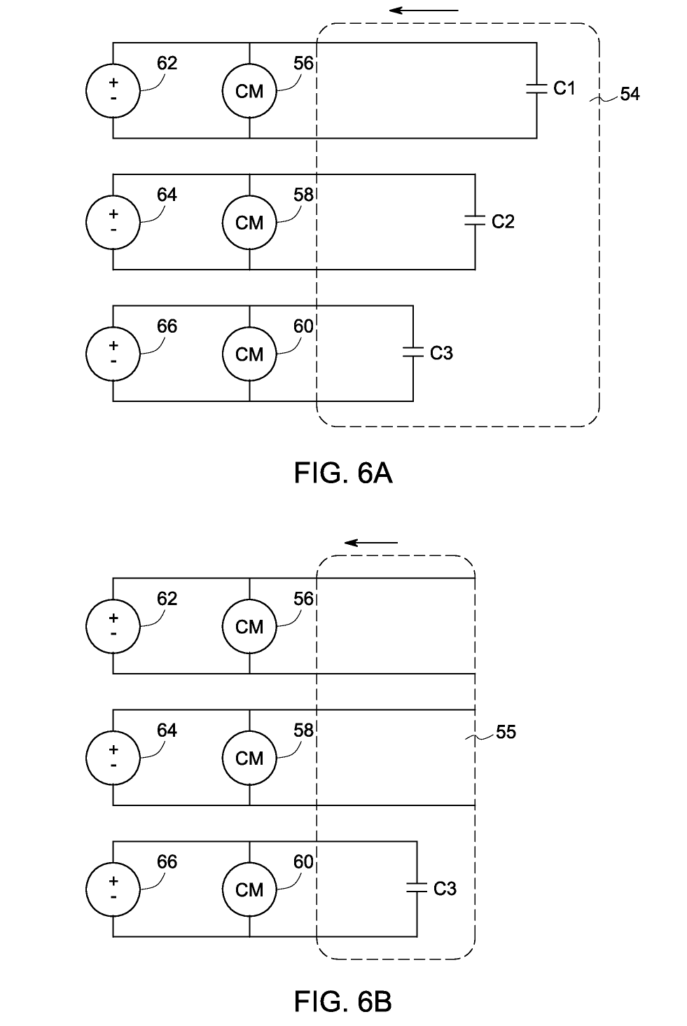

Referring now to the drawings, embodiments of the sensor system are generally shown and referred to in FIG. 1, through FIGS. 6A and 6B. In FIG. 1, the sensor system includes a sensor comprising a resistive sensing element 2. The sensor system further comprises a measuring device 8, which may be a voltmeter, for example. The sensor system may further comprise a substrate 4, and the resistive sensing element may be disposed directly on the substrate. In an alternative embodiment, the resistive sensing element may be disposed over intervening elements or other layers of materials. In yet another embodiment, the resistive sensing element may be disposed within the substrate itself.

A power supply 6 may be used to provide an alternating current (AC) or a direct current (DC) to the sensor circuit, including the resistive sensing element 2. The resistive sensing element 2 may be configured for optimal operational resistance. In one embodiment, the sensing element 2 may be operative in association with the substrate 4. In an alternate embodiment of the example, the sensing element 2 may be operative while it is present as a monolithic feature, without a separate substrate being present. In a non-limiting example, the resistive sensor may be used to measure temperature or other environmental changes or events in a high-temperature, harsh environment application.

The resistive sensing element may be adapted to have a meandering design (e.g., irregular, with no specific direction or pattern), or a serpentine design or the like, to provide increased sensor response to any change in the material property of the sensing element. In some embodiments, the resistive sensing element may be configured in a shape selected from serpentine, criss-cross, circular, rectangular, square, linear, irregular or a combination of any of these shapes.

The sensor system may further comprise a measuring device to enable the measurement of at least one change in an electrical property. The electrical property can be measured across the electrical sensing element. As an example, a voltmeter may be present in the sensor system, wherein the voltmeter measures a voltage under known current conditions, so that the resistance of the sensor can be determined by using the formula V=I×R. The change in voltage is directly proportional to the change in resistance of the resistive sensor material. In one example, a change in environmental conditions, such as for example, a change in temperature, will affect the resistivity of the sensor material, which will in turn be reflected by a change in the measured voltage under known current conditions. In another example, the resistance of a resistive sensing element, as determined by measuring the voltage drop across the element under known current conditions, may change as a result of recession of the material in which the sensor is embedded due to erosion, corrosion, wear, or a combination of these. As the resistive sensing element recedes with its matrix, the measured electrical resistance increases.

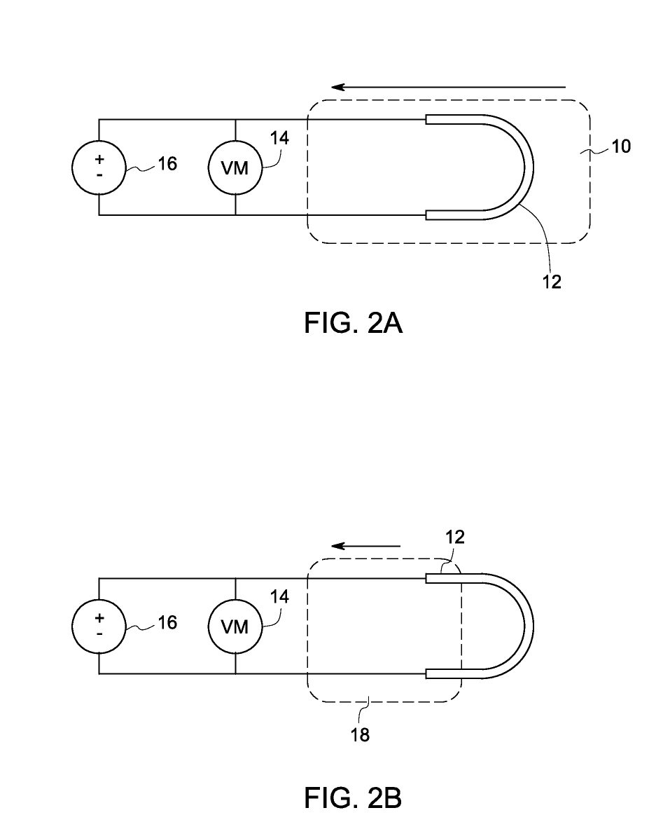

FIGS. 2A and 2B show a sensor system, where a resistive sensing element (12) is disposed on a substrate (10). The substrate is a refractory brick. The sensor includes a voltmeter 14 and a power supply 16. The sensing element 12 is able to sense environmental changes. In one example, this environmental change may be temperature. As an example, the substrate (10) can erode from right to left (as shown by an arrow, both in FIGS. 2A and 2B), resulting in a substrate (18) of decreased volume, as shown in FIG. 2B. For example, the change in volume may result from a change in length, width, or thickness. The sensing element (12) remains intact in FIG. 2B, and the resistive sensing element is able to sense changes in the environment, even after erosion or degradation of the substrate. In one embodiment, the substrate may be a gasifier refractory brick. In that case, the sensor may reflect an increase in temperature as the insulating brick erodes in the harsh gasifier environment. The resistive sensor 12 may be present as a monolithic piece without a substrate. In one embodiment, the resistive sensor 12 may be disposed on a substrate that is more resistant to erosion than the refractory brick. In yet another embodiment, the resistive sensor in FIG. 2A may erode with the brick, thus indicating recession of the brick by a sharp increase in the resistance.

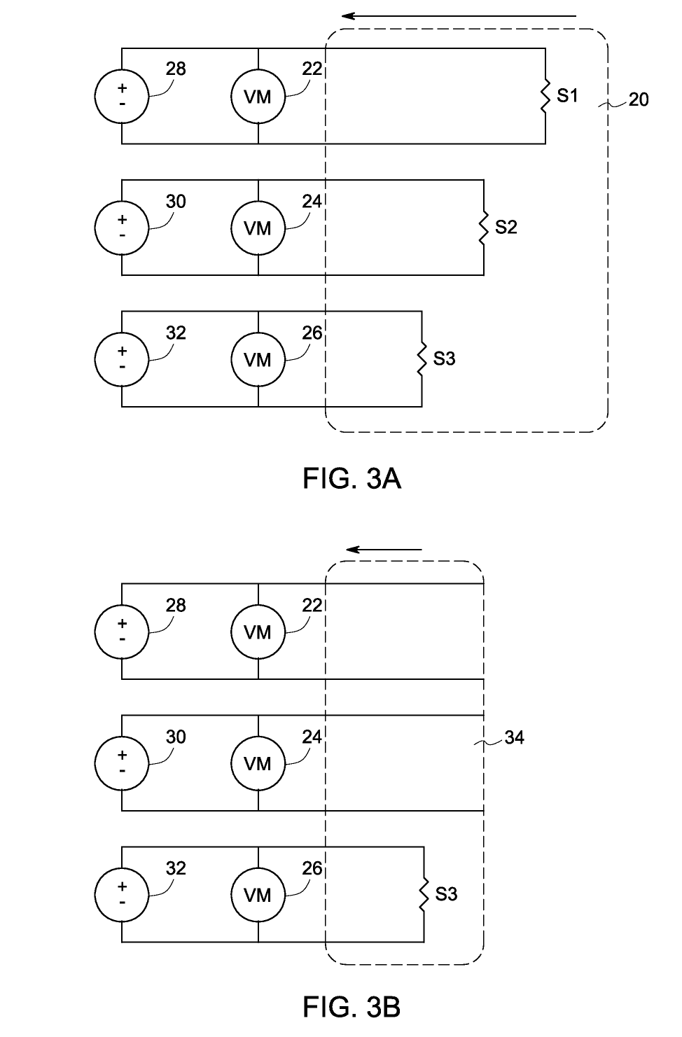

The sensor system, in some embodiments, may comprise two, three, four, or more sensors, each comprising an electrical sensing element. As one illustration, FIGS. 3A and 3B show a sensor system comprising three discrete sensors S1, S2 and S3. The sensors are disposed on a substrate 20 in FIG. 3A. In one embodiment, the substrate (20) is a refractory brick present in a gasifier. Each sensor (51, S2 and S3) has a separate voltmeter (22, 24, and 26 respectively) and a power supply (28, 30, and 32 respectively). Each sensor is capable of measuring a sensor resistance, which may result from a change in at least one environmental condition. In one non-limiting example, the sensors are able to measure a change in resistance, which may result from a change in temperature. In a specific embodiment, the substrate (20) may be prone to an environmental condition or environmental event that causes a decrease in volume, or may cause erosion, from the right side to the left (as shown by an arrow in FIGS. 3A and 3B), resulting in a substrate with a reduced volume (34), as shown in FIG. 3B. As a result, S1 and S2 have been damaged, causing a drastic increase in resistance. The situation may result in an open circuit. The sensor S3, which remains intact even after erosion or degradation of the substrate (as shown in FIG. 3B) may be used to measure the intensity of damage. Furthermore, the resistance across sensor S3 may be used to detect the change in temperature

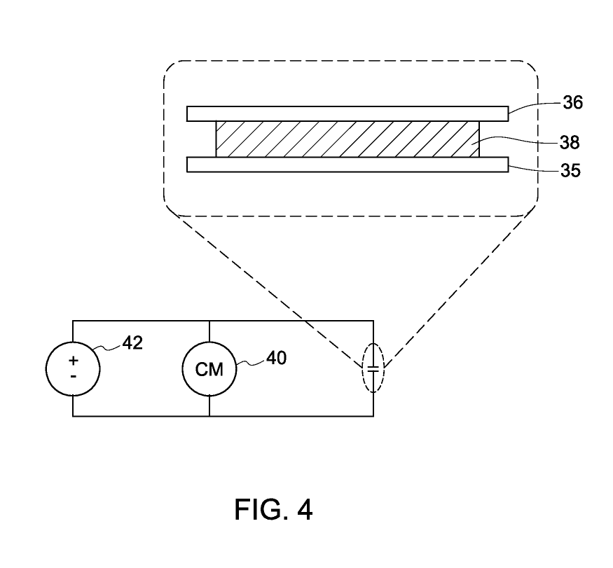

In the embodiment of FIG. 4, the sensing element is a parallel plate capacitor, comprising a pair of parallel conductors, i.e., sensor element plates (35, 36) separated by an electrically insulating substrate (38), forming a “sandwich”. The space covered by the capacitive sensing element disposed on the substrate may be described as a sensing region. The electrical sensing circuit may comprise a measuring device. The measuring device may be a capacitance meter (40). The sensor system may also comprise a power supply (42) for delivering electrical power to the electrical sensing element. A potential difference may result between the conductors upon activation of the power supply 42. The electrical power supply may be an alternating current (AC) or a direct current (DC) power supply.

In one example, the substrate material has a dielectric constant ∈ᵣ that may change as a function of an environmental condition. In one embodiment, the capacitive sensor element measures a change in capacitance, based on the change in the substrate dielectric constant, as a function of temperature. In other embodiments, the environmental events may include a chemical change or a thermo-chemical change.

The capacitance of the parallel plate sensing element is given by,

C=∈ᵣ.∈ₒ.A/d;

where C is capacitance in Farads (F), A is the area of overlap of the two plates, measured in square meters, d is the separation between the plates, measured in meters, ∈ᵣ is relative static permittivity (sometimes called the dielectric constant) of the material between the plates, and ∈ₒ is the permittivity of free space, where ∈₀=8.854×10⁻¹² F/m. If change in plate area is represented by ΔA, and the change in capacitance is represented by ΔC; then:

ΔC=∈ᵣ.∈ₒ.ΔA/d.

Therefore, ΔC can be measured using a capacitance meter. Because ΔC is proportional to ΔA, the change in capacitance provides a direct measure of the change in plate dimension that may result from environmental changes.

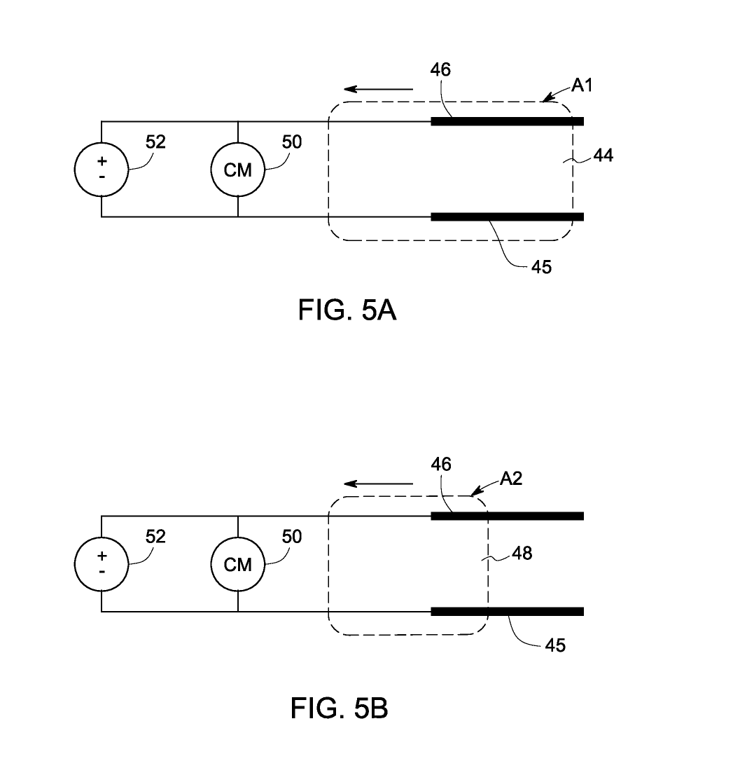

In one example, a change in the area of a substrate may result from a change in a dimension of the substrate. The change in substrate-dimension may result from a change in temperature. For an alternative example, even though at a constant temperature condition, the substrate volume is reduced due to corrosion or erosion, resulting in a change in capacitance. Therefore, a change in substrate-dimension is proportional to a change in capacitance, as illustrated in FIGS. 5A, through 6B. In one embodiment, the substrate is a refractory brick in a gasifier system, and the change in environmental condition causes brick (substrate) wear, which results in a change in volume of the substrate. In one embodiment, the volume of the substrate recedes, where the dielectric property remains unchanged (as shown in FIGS. 5A and 5B). In an alternative embodiment, a change in the dielectric property is possible, due to recession of the dielectric layer between the electrodes. In another alternate embodiment, there may be a change in the capacitive sensing element, while the volume of the substrate remains constant. In FIGS. 6A and 6B, physical deterioration of the capacitive elements is caused by recession of the brick.

FIGS. 5A and 5B show a capacitive sensing element (46) disposed on a substrate (44) (e.g., refractory brick) with a characteristic dielectric constant, ∈ᵣ. In one embodiment, this substrate is a refractory brick in a gasifier. The capacitive sensing element is connected to a power supply (52) that delivers electrical power to the element, and a capacitive measuring device to measure the capacitance (capacitance meter or CM) (50). The measured initial capacitance, C₁, can be represented by:

C₁=∈ᵣ.∈ₒ.A₁/d

wherein, ∈ₒ is the permittivity of free space, A₁ is the area of the parallel capacitor plates (as shown in FIG. 5A), and d is the distance between the parallel plates. The substrate (44) (with area A1) erodes from right to left, resulting in a substrate (48) of decreased volume, with a resulting area A2, shown in FIG. 5B. The capacitive sensing element (46) remains intact, even after the environmental change or event. The area of the substrate covered by the capacitance sensing elements is now A₂ (as shown in FIG. 5B). Therefore, the area under the capacitance sensing elements that is no longer present is (A₁-A₂). The area of the substrate has decreased, which changes the capacitance of the sensor element. The capacitance in the absence of a dielectric material, Cₒ, is represented by:

C₀=∈₀∈₂(A₁−A₂)/d

The capacitance of the portion of the sensor element that still has a substrate between it, C₂, can be represented by:

C₂=∈ᵣ∈₀A₂/d

Therefore, the equivalent capacitance after erosion of the substrate, C_{eq}, in which the substrate partially fills the area between the parallel capacitance sensor element, is:

C_{eq}=C₀+C₂=∈₀∈₂(A₁−A₂)/d+∈ᵣ∈₀(A₂)/d

Therefore, after substrate erosion, the capacitance C₀ of the sensor will decrease, such that C₀<C₁. Therefore, the equivalent capacitance C_{eq} is a function of the change in area, and a function of the relative permittivity ∈ᵣ of the area.

In another embodiment, the sensor element in FIG. 5A is subject to recession along with the refractory brick, such that:

C₀=∈ᵣ∈₀A₁/d

and:

C₂=∈ᵣ∈₀A₂/d

Therefore, the equivalent capacitance after erosion of the sensor element and substrate, C_{eq}, in which the substrate fills the area between the parallel capacitance sensor element, is:

C_{eq}=C₂=∈ᵣ∈₀A₂/d

such that C_{eq}<C₀.

FIGS. 6A and 6B show a sensor system utilizing three capacitive sensing elements, C₁, C₂ and C₃. All sensor elements are disposed on a substrate (54). In one embodiment, the substrate is a gasifier refractory brick. Each sensor (C₁, C₂ and C₃) has a separate capacitance voltmeter (56, 58, and 60 respectively) and a separate power supply (62, 64, and 66 respectively). Each sensor is able to measure a sensor capacitance which may result from a change in at least one environmental condition. The substrate erodes with environmental changes from right to left (as shown by an arrow in FIGS. 6A and 6B), resulting in a substrate of reduced volume (55). The erosion can, for example, result in the destruction of C₁ and C₂. As C₁ and C₂ are not able to supply any capacitive signal, and C₃ remains intact, the capacitive signal in C3 may be used to determine the eroded volume (55 in FIG. 6B) of the substrate.

As noted above, harsh environmental conditions, such as corrosion or erosion, may affect the dimension of a substrate, which may result in a change in capacitance of the sensing element. A capacitance meter may be used to monitor the change in capacitance due to changes in substrate dimension.

In one embodiment, the substrate may be a refractory brick. The area or volume of the refractory brick may change with a change in environmental conditions, or with operational harsh environmental conditions. Prolonged exposure of refractory brick to a thermo-chemical environment causes degradation in the brick. These environmental or operational conditions can result in brick wear, which results in a change in volume of the substrate material, as shown in FIGS. 6A and 6B. Hence, the destruction of capacitors may occur with changes in the area or volume of the substrate material, resulting in the measurement of the amount of brick wear.

The substrate of the sensor system can comprise an insulator material. In one embodiment, the substrate is an electrically non-conductive material. In another embodiment, the substrate may comprise a refractory material, such as a refractory oxide material. The material may be selected from oxides, nitrides or combinations thereof. In a specific embodiment, the refractory material is aluminum nitride (AlN). The sensor material may be applied to a dense AlN substrate via thermal spray, physical vapor deposition, screen-printing, and other methods known in the art. The sensor material can be subsequently patterned into the requisite sensor geometry. In one embodiment, an MN insulating layer may be disposed onto or within the refractory brick wall, using various techniques known in the art, including a slurry deposition process, such as screen-printing.

As the substrate is also used in association with the sensor in harsh environmental conditions, the material of the substrate must also be resistant to such conditions. For example, the material of substrates for use in gasifier applications must be resistant to degradation at a temperature of at least about 1600° C., and a pressure of at least about 600 PSIG. In some embodiments, the substrate material is also resistant to degradation at a water vapor concentration of at least about 10%.

In many embodiments, the substrate for the capacitive or resistive sensing element comprises a dielectric refractory material. As a non-limiting example, the wall of a gasification chamber typically comprises refractory bricks, which can serve as a substrate for a sensor used in a gasification system. In one example, the sensor system may be incorporated inside a refractory brick of the chamber wall, so that the wall serves as the substrate of the sensor element. The sensor disposed within the brick wall may respond to changes in a physical, electrical, or chemical property, as described above, as the brick wall erodes. In other instances, e.g., using the resistive sensor element embodiment, the sensor element is disposed over the refractory brick substrate.

A method for selectively detecting at least one environmental condition in a gasification chamber comprises the deposition of at least one sensor on a wall of the gasification chamber; wherein at least one sensor comprises an electrical sensing element. The sensing element may be disposed on a substrate. In some embodiments, at least one brick in the wall of the gasification chamber is used as the substrate for the sensing element.

The method further comprises measurement of parameters, and the detection of at least one environmental condition in a gasification chamber, wherein the conditions are those described previously.

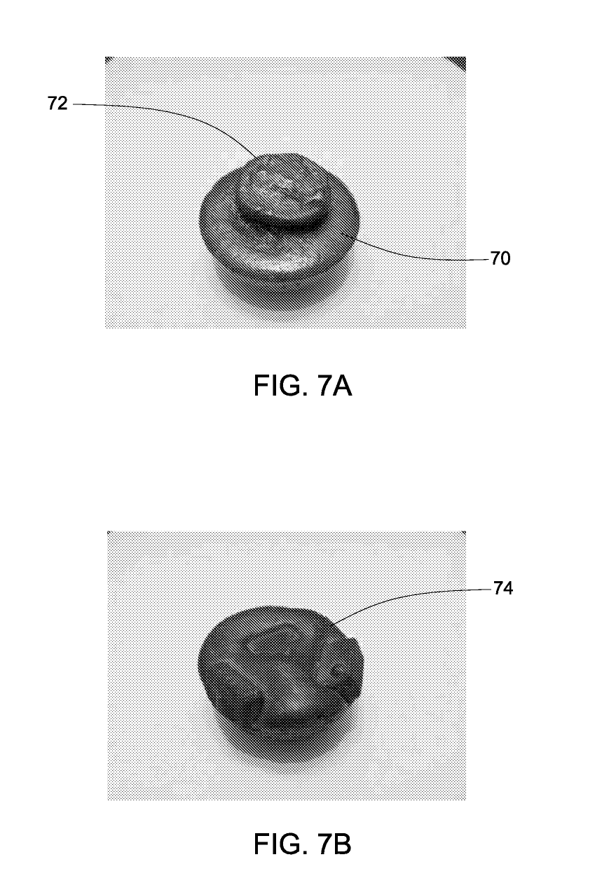

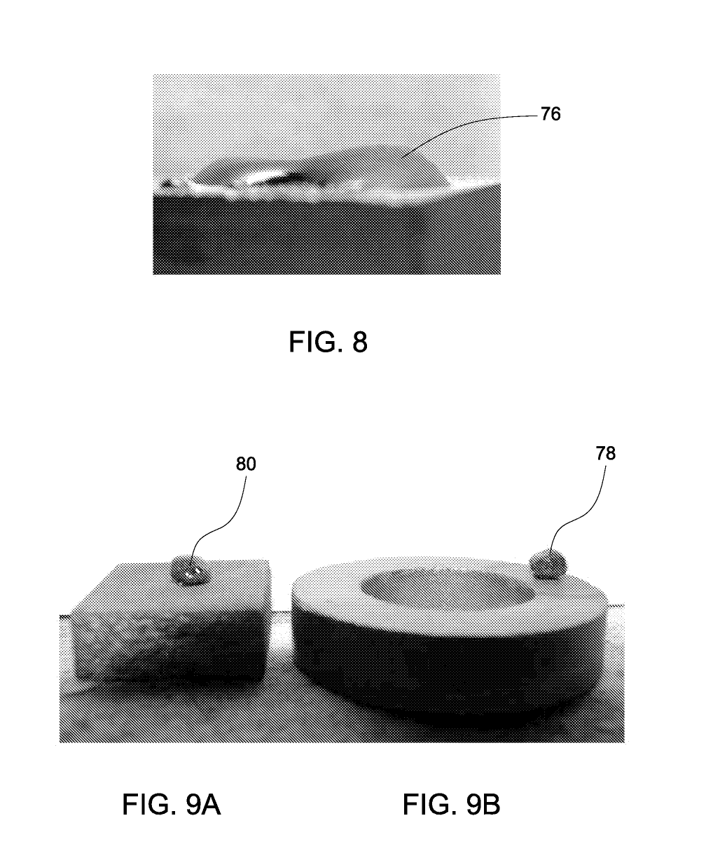

The harsh environment resistance of a representative sensor material was tested using cast iron samples, with and without a coating of the refractory composite material, and the results are depicted in FIGS. 7A and 7B, respectively. In another example, a Hexylloy™ material (commercial silicon carbide) was tested for slag and temperature resistance, and the results are depicted in FIGS. 8 through 9A and 9B.

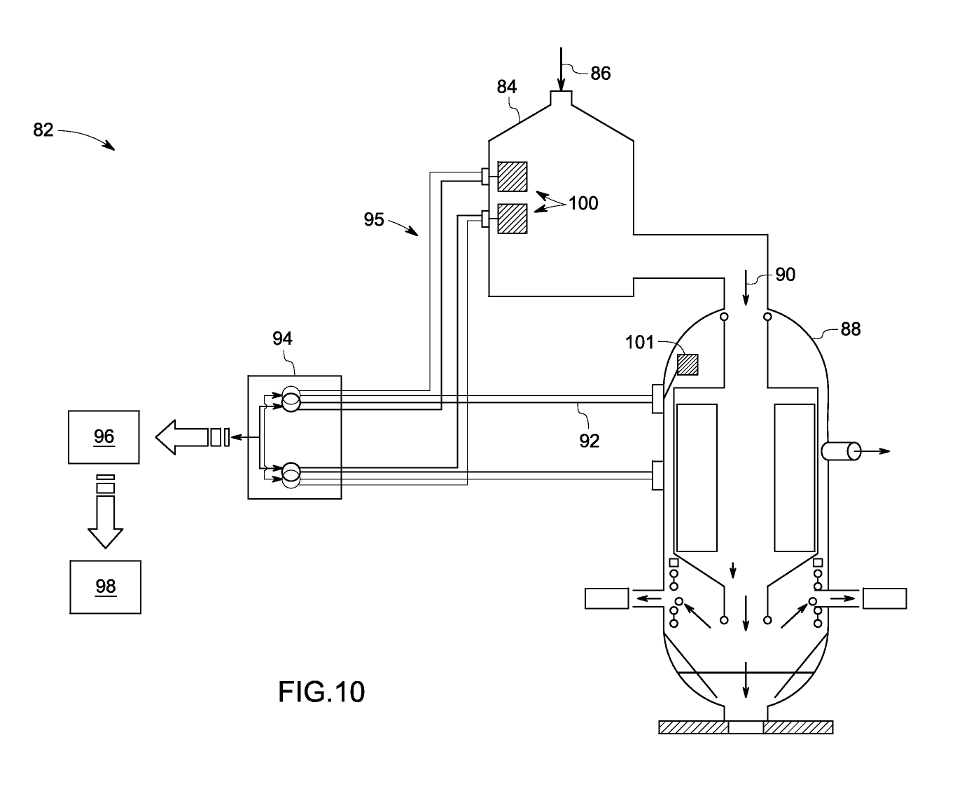

Referring now to a drawing, FIG. 10 shows an exemplary system: a gasification system including a gasifier unit and a radiant syngas cooler (RSC). The gasification system is an apparatus for converting carbonaceous materials, such as coal, petroleum, petroleum coke, biomass, or methane, hydrogen sulfide, or water vapor, into carbon monoxide, hydrogen, and carbon dioxide. FIG. 10 describes a gasification system 82, including a gasifier unit 84, with a coal slurry feed injector 86. The combustion gases (syngas), slag, ash, and coal are introduced into the RSC 88 from gasifier outlet 90, and the produced syngas is delivered to an external gas turbine by pipeline. Electrical signal cables 92 and 95 are used for delivering an electrical response from sensors 100 and 101 in the gasifier unit and RSC, respectively, to terminate in the junction box 94. Sensors can be disposed on the inner walls, and/or along the platen edge of the RSC, while others are projected in the gas stream of the radiant syngas cooler. The sensing signal interrogation system 96 can be remotely located in a control room. The data is processed and analyzed with a computer 98.

The sensor response in a gasification system can be used to maintain the optimum conditions inside the gasification chamber. In a specific embodiment of a gasification system, a chemically reactive environment includes oxidizing environments, reducing environments, or corrosive environments, as noted previously. For a gasification system, corrosion from sulfur compounds, chlorides, ammonia, and slag (e.g., CaO—Al₂O₃—SiO₂—FeO—MgO) are common. In a gasification system, mechanical stresses from material strain, due to thermal cycling and thermal mismatches, are problems that need to be addressed. The movement of the slag in a downward direction, and the degradation of large pieces of debris in the gasification chamber, result in erosion in the chamber. Additionally, in the gasifier environment, thermo-chemical interactions are common, where a change in substrate chemistry results from chemically reactive species which are subjected to elevated temperatures in the environment. Therefore, a measurement of parameters inside the system, or within any particular reaction unit, may be critical for ensuring a stable and optimum condition in the system. Thus, the gasification system or chamber may include one or more resistive sensors or capacitive sensors.

### Example 1

### Determination of the High Temperature Resistant Properties of the Sensor Material

In one example, the environmental resistance of the sensor material was tested, using cast iron samples, by exposing the samples to a highly reactive copper (Cu) melt in vacuum, at a temperature of at least 1085° C. The composition of the composite material (in volume percent) is 66.9% SiC, 8.1% (Mo,W)₅Si₃C and (Mo,W)₅Si₃, 6.9% (Mo,W)Si₂, and 18.1% volumetric porosity. The Novotnyi phase, (Mo,W)₅Si₃C, and (Mo,W)₅Si₃ were not distinguishable using scanning electron microscopy, and therefore they are included together when reporting composition. The tungsten to molybdenum atomic ratio for (Mo,W)₅Si₃C and (Mo,W)₅Si₃ is 0.28; and the tungsten to molybdenum atomic ratio for (Mo,W)Si₂ is 0.19. The silicides are all silicon stoichiometric.

In a control set, an uncoated cast iron part was exposed to a Cu melt (74), as shown in FIG. 7B. In a test sample, the cast iron part was coated with the composite material (72), as shown in FIG. 7A. In the presence of the composite material coating, there is no mixing of the cast iron material with the copper melt for the test sample. However, for the control set, which did not have the coating, the cast iron material undesirably interacted with the copper melt (74). Therefore, the sensor material has the ability to withstand elevated temperature conditions.

### Example 2

### Determination of the Thermo-Chemical Resistance of the Sensor Material in a Gasifier

In another example, a Hexylloy™ (commercial silicon carbide) part was used as a control, and remained uncoated (as shown in FIG. 8). The part was exposed to slag at a temperature, which is in a range from about 1400° C. to 1500° C., in vacuum. The slag was in a liquid form at these high temperatures. The Hexylloy™ part was then cooled to room temperature. The surface of the part showed a small wetting angle. Hence, in the thermo-chemical environment, the slag (76) (in FIG. 8) was found to stick and easily spread over the surface of the Hexylloy™ part, thereby corroding the part.

To determine sensor material properties in a similar environment, two different sample parts were tested. One was made of a bulk slab of refractory silicon carbide composite material, with a composition similar to that described in example 1 (FIG. 9A). The other sample was formed of a Hexylloy™ material, coated with a film of a similar refractory silicon carbide composite material as mentioned above (FIG. 9B). The parts were exposed to a gasifier slag in a vacuum at high temperatures between 1400° C. and 1500° C., where the slag was in a liquid form, and the samples were then cooled to room temp. The surface of the parts showed non-wetting behavior for both the bulk refractory silicon carbide composite (80) sample and the Hexylloy™ sample coated with refractory silicon carbide composite (78). The corrosive material did not wet the refractory silicon carbide composite bulk and coated parts, resulting in reduced corrosion. Hence, the composite sensor material has the ability to withstand the harsh environment conditions representative of a gasifier.

### Example 3

### Resistive Sensor Response to Temperature Change

A sensor system was designed to include a sensor comprising a resistive sensor material, a pair of electrodes, a substrate, and a voltage-measuring device. The resistive sensor material used was a refractory silicon carbide composite material with the same composition as mentioned in Example 1. For the composite material sensor, platinum wires were used for the electrical circuit. Platinum wires were attached to two sides of the sensor. A platinum slurry was used to make the electrical contact between platinum wires and the refractory silicon carbide material. The slurry was heat treated to sinter the platinum in an inert atmosphere, resulting in an arrangement for resistance measurement as shown in FIG. 1. Two additional platinum wires were attached to one side of the sensor. One of the wires was attached to a power supply, and the other wire was attached to a voltmeter used to monitor the voltage across the sensor. The opposite side of the sensor had an identical configuration, wherein two platinum wires were joined to the power supply and voltmeter, respectively. The sensor was then placed in a furnace and exposed to an atmosphere of He with 5% H₂. The temperature of the furnace was increased to 1090° C., and the supplied current was about 0.4 Amp. The voltmeter was used to monitor the voltage as a function of temperature, and the resistance of the refractory SiC was calculated using the equation V=IR.

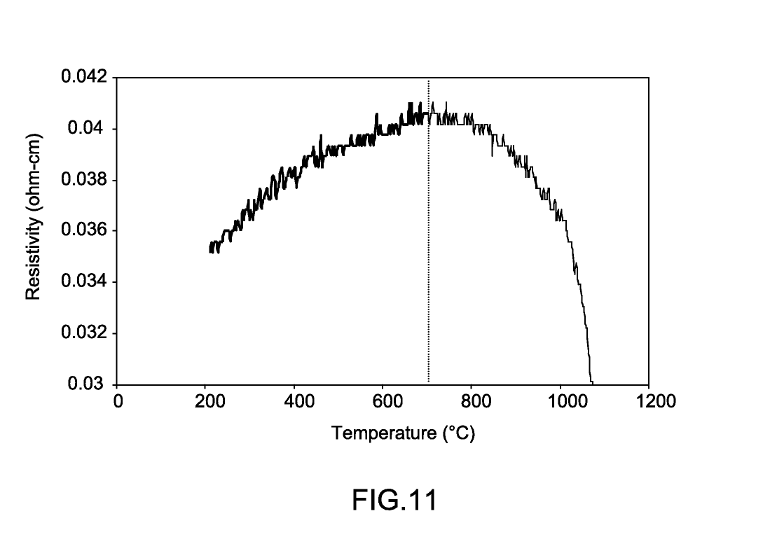

The sensor response for the above mentioned test is illustrated in the graph shown in FIG. 11. The resistance value shows an increase (as shown by a thick lined-upward curve before a dotted vertical line in FIG. 11) with increase in temperature, starting from about 200° C. to about 700° C. The graph also shows an unexpected decrease in the measured resistance (as shown by a thin lined-downward curve, after a dotted vertical line in FIG. 11) as the temperature was further increased to 1100° C. The probable reason for this unexpected decrease in resistance is due to sintering of the platinum wires to the sensor material. The plausible reason for the decrease in resistance does not appear to be a limitation of the material itself, but likely a limitation of the material of the connecting wires. Proper optimization of the contact material is required to address this limitation. It is expected that the use of a more appropriate contact material may reduce this artifact, and may reflect clearly the continuous increase of resistivity with increasing temperature. Therefore, in accordance with one embodiment, a high temperature environmental condition can be determined by using a sensor comprising the resistive sensing element.

While only certain features of the invention have been illustrated and described herein, many modifications and changes will occur to those skilled in the art. It is, therefore, to be understood that the appended claims are intended to cover all such modifications and changes as fall within the scope of the invention.

1. A sensor system comprising at least one sensor which includes an electrical sensing element comprising a composite material selected from the group consisting of:
(a) i) silicon carbide (SiC)
ii) (Mo,W)₅Si₃C; and
iii) (Mo,W)Si₂; and
(b) i) (Mo,W)₅Si₃C;
ii) (Mo,W)Si₂; and
iii) (Mo,W)₅Si₃.

2. The sensor system of claim 1, wherein the ratio of tungsten to molybdenum (molar %) in the composite material is in the range from about 0:1 to about 9:1.

3. The sensor system of claim 1, wherein constituents in the composite material are present in following amounts (volume %):

| (Mo,W)₅Si_{3;} or (Mo,W)₅Si₃C | About 15% to about |
|---|---|
| | 85% |
| silicon carbide | about 2% to about |
| | 85% |
| (Mo,W)Si₂ | about 0.8% to about |
| | 55%; |

4. The sensor system of claim 1, further comprising a substrate, wherein the electrical sensing element is disposed on the substrate.

5. The sensor system of claim 1, further comprising a power supply which is capable of delivering electrical power to the electrical sensing element; and a measuring device to measure at least one change in an electrical property across or within the electrical sensing element caused by an environmental event, or by at least one change in an environmental condition.

6. The sensor system of claim 1, wherein the electrical sensing element is a resistive sensing element or a capacitive sensing element.

7. A sensor system, comprising:
(I) at least one sensor which comprises a resistive sensing element, wherein the resistive sensing element is formed of a composite material selected from the group consisting of:
(a) i) silicon carbide (SiC)
ii) (Mo,W)₅Si₃C; and
iii) (Mo,W)Si₂; and
(b) i) (Mo,W)₅Si₃C;
ii) (Mo,W)Si₂; and
iii) (Mo,W)₅Si₃.
(II) a power supply capable of delivering electrical power to the resistive sensing element; and
(III) a voltage measuring device to measure a voltage difference across the resistive sensing element:
wherein the voltage difference is caused by an environmental event, or by at least one change in an environmental condition.

8. The sensor system of claim 7, wherein the resistive sensing element is disposed on or embedded within a substrate.

9. The sensor system of claim 8, wherein the substrate material is an insulator material.

10. The sensor system of claim 9, wherein the substrate material comprises at least one oxide, nitride, or a combination thereof.

11. The sensor system of claim 7, wherein the environmental condition is selected from temperature, pressure, humidity, or a combination of at least two of these conditions.

12. The sensor system of claim 7, wherein the resistive sensing element is configured in a shape selected from the group consisting of serpentine, irregular, criss-cross, circular, rectangular, square, linear, or a combination thereof.

13. A gasification system comprising the sensor of claim 7.

14. A sensor system, comprising:
(I) at least one sensor which comprises a capacitive sensing element, wherein the capacitive sensing element comprises two electrodes; and is formed of a composite material selected from the group consisting of:
a) i) silicon carbide (SiC)
ii) (Mo,W)₅Si₃C; and
iii) (Mo,W)Si₂; and
b) i) (Mo,W)₅Si₃C;
ii) (Mo,W)Si₂; and
iii) (Mo,W)₅Si₃.
(II) a power supply capable of delivering electrical power to the capacitive sensing element; and
(III) a capacitance measuring device to measure a capacitance across the capacitive sensing element,
wherein the sensor is responsive to at least one environmental condition or environmental event.

15. The sensor system of claim 14, wherein the capacitive sensing element is a component of a capacitor, and the capacitor comprises a pair of conductors separated by a non-conductive substrate, so that a potential difference exists between the conductors, and upon activation of the power supply, the potential difference provides a selected capacitance.

16. The sensor system of claim 15, wherein the substrate has a selected volume between the conductors, and a change in at least one environmental condition or environmental event causes a change in the selected volume, and a consequential change in the selected capacitance, which is capable of being measured by the capacitance measuring device.

17. The sensor system of claim 15, wherein the substrate comprises a refractory brick.

18. A gasification system comprising the sensor of claim 15.

19. A gasification system comprising:
a gasifier; and
at least one sensor system disposed on or within at least one wall of the gasifier, wherein the sensor system comprises:
(I) at least one sensor which includes an electrical sensing element comprising a composite material selected from the group consisting of:
a) i) silicon carbide (SiC)
ii) (Mo, W)₅Si₃C; and
iii) (Mo,W)Si₂; and
b) i) (Mo,W)₅Si₃C;
ii) (Mo,W)Si₂; and
iii) (Mo,W)₅Si₃;
(II) a power supply delivering electrical power to the electrical sensing element; and
(III) an electrical property-measuring device to measure an electrical property across the electrical sensing element.

20. The gasification system of claim 19, wherein the electrical sensing element of the sensor is in contact with a selected region of the gasifier wall, having a selected dimension; and a change in at least one environmental condition or environmental event causes a change in the selected dimension, which causes a consequential change in an electrical property, which is capable of being measured by the electrical property-measuring device.

21. A method for selectively detecting at least one environmental condition in a gasification chamber, comprising the steps of disposing at least one sensor on or within a wall of the gasification chamber; wherein the sensor comprises:
(I) an electrical sensing element disposed on a substrate, and the electrical sensing element comprises a composite material selected from the group consisting of:
a) i) silicon carbide (SiC)
ii) (Mo,W)₅Si₃C; and
iii) (Mo,W)Si₂; and
b) i) (Mo,W)₅Si₃C;
ii) (Mo,W)Si₂; and
iii) (Mo,W)₅Si₃.
(II) a power supply delivering electrical power to the electrical sensing element; and
(III) a measuring device to measure at least one difference in an electrical property across or within the electrical sensing element; wherein the environmental condition generates a sensor response by changing the electrical property of the electrical sensing element.
